(19) United States
(12) Patent Application Publication
(10) Pub. No.: US 2024/0234627 A1
(43) Pub. Date: Jul. 11, 2024

(54) CHAMBERS, METHODS, AND APPARATUS FOR GENERATING ATOMIC RADICALS USING UV LIGHT

(71) Applicant: Applied Materials, Inc., Santa Clara, CA (US)

(72) Inventors: Abbas RASTEGAR, Schenectady, NY (US); Shawn THOMAS, Chesterfield, MO (US)

(21) Appl. No.: 18/094,765

(22) Filed: Jan. 9, 2023

(51) Int. Cl. H01L 33/08; H01L 33/00; H01L 33/24; H01L 33/48; H01S 5/0222

(52) U.S. Cl. CPC H01L 33/08; H01L 33/0083; H01L 33/24; H01L 33/483; H01S 5/0222

(57) ABSTRACT

The present disclosure relates to chambers, methods, apparatus, and related components for treating substrates. In one or more implementations, atomic radicals are generated using ultraviolet light, and the atomic radicals are used to treat a substrate. In one implementation, a chamber applicable for use in semiconductor manufacturing includes an internal volume defined at least partially by one or more sidewalls, one or more substrate supports disposed in the internal volume, one or more transfer openings, a gas line fluidly connecting to the internal volume from outside of the internal volume, and an ultraviolet (UV) unit. The UV unit includes one or more UV light sources configured to generate UV light having a wavelength that is within a range of 170 nm to 254 nm.

### BACKGROUND

### Field

Embodiments of the present disclosure relate to chambers, methods, apparatus, and related components for treating substrates. In one or more implementations, atomic radicals are generated using ultraviolet light, and the atomic radicals are used to treat a substrate.

### Description of the Related Art

Semiconductor substrates are processed for a wide variety of applications, including the fabrication of integrated devices and microdevices. Substrates can undergo a variety of processing operations, which can involve hindrances. As an example, substrates can undergo cleaning to remove native oxide layers prior to epitaxial deposition processing—otherwise the native oxide layers can hinder epitaxial deposition operations. The cleaning can cause particle generation on the substrate, which can hinder other processing operations and device performance. Efforts to address such issues can be complex and expensive, and can involve increased consumption of space.

Therefore, a need exists for chambers, apparatus, and methods that facilitate reduced particle generation and enhanced device performance in a manner that is cost-effective, modular, and simple.

### SUMMARY

The present disclosure relates to chambers, methods, apparatus, and related components for treating substrates. In one or more implementations, atomic radicals are generated using ultraviolet light, and the atomic radicals are used to treat a substrate.

In one implementation, a chamber applicable for use in semiconductor manufacturing includes one or more sidewalls, an internal volume defined at least partially by the one or more sidewalls, one or more substrate supports disposed in the internal volume, one or more transfer openings formed in the one or more sidewalls, a gas line fluidly connecting to the internal volume from outside of the internal volume, and an ultraviolet (UV) unit. The UV unit includes one or more UV light sources configured to generate UV light having a wavelength that is within a range of 170 nm to 254 nm.

In one implementation, an apparatus applicable for use in semiconductor manufacturing includes a gas line at least partially formed of a UV transparent material, the gas line including a flow volume, and an ultraviolet (UV) unit including a line opening and configured to be disposed at least partially about the gas line such that the gas line extends through the UV unit. The UV unit includes one or more arcuate bulbs configured to be disposed at least partially around the gas line, and one or more UV light sources disposed in the one or more bulbs. The one or more UV light sources generates UV light, the UV light having a wavelength that is within a range of 170 nm to 400 nm.

In one implementation, a method of processing substrates includes flowing an inert gas toward an internal volume of a chamber, and generating ultraviolet (UV) light toward the inert gas. The UV light has a wavelength that is within a range of 170 nm to 400 nm. The method includes generating atomic radicals of the inert gas, and treating a surface of a substrate with the atomic radicals while the substrate is positioned in the internal volume of the chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic diagram top plan view of a processing system, according to one implementation.

FIG. 2 is a schematic cross-sectional side view of a load lock chamber, according to one implementation.

FIG. 3 is a schematic top view of a UV unit positioned above a substrate, according to one implementation.

FIG. 4 is a schematic cross-sectional side view of a load lock chamber, according to one implementation.

FIG. 5 is a schematic cross-sectional side view of a load lock chamber, according to one implementation.

FIG. 6 is a schematic cross-sectional side view of a load lock chamber, according to one implementation.

FIG. 7 is a schematic cross-sectional view of the UV unit shown in FIG. 6, along Section 7-7 shown in FIG. 6, according to one implementation.

FIG. 8 is a schematic cross-sectional side view of a processing chamber according to one implementation.

FIG. 9 is a schematic block diagram view of a method of processing substrates, according to one implementation.

FIG. 10 is a cross-sectional view of a load lock chamber, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to chambers, methods, apparatus, and related components for treating substrates. In one or more implementations, atomic radicals are generated using ultraviolet light, and the atomic radicals are used to treat a substrate.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

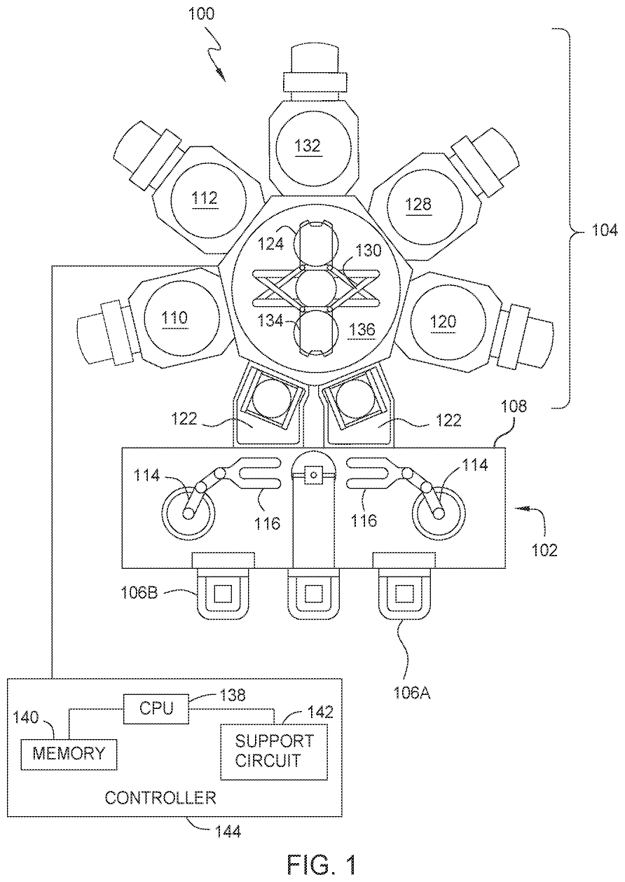

FIG. 1 is a schematic diagram top plan view of a processing system 100, according to one implementation. The processing system 100 includes one or more substrate load lock chambers 122, a vacuum-tight processing platform 104, a factory interface 102, and a controller 144. The substrate load lock chambers 122 may be load lock chambers. In one embodiment, the processing system 100 may be a CENTURA® integrated processing system, commercially available from Applied Materials, Inc., located in Santa Clara, California. It is contemplated that other processing systems (including those from other manufacturers) may be adapted to benefit from the disclosure.

The platform 104 includes a plurality of processing chambers 110, 112, 128, 120, 132 and the one or more substrate load lock chambers 122 that are coupled to a vacuum substrate transfer chamber 136. Two substrate load lock chambers 122 are shown in FIG. 1. The factory interface 102 is coupled to the transfer chamber 136 through the substrate load lock chambers 122.

In one or more embodiments, the factory interface 102 includes at least one docking station 108 and at least one factory interface robot 114 to facilitate the transfer of substrates. The docking station 108 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the substrate load lock chambers 122, to the processing platform 104 for processing. Substrates being transferred can be stored at least temporarily in the substrate load lock chambers 122.

Each of the substrate load lock chambers 122 has a first port interfacing with the factory interface 102 and a second port interfacing with the transfer chamber 136. The substrate load lock chambers 122 are coupled to a pressure control system (not shown) which pumps down and vents the substrate load lock chambers 122 to facilitate passing the substrates between the vacuum environment of the transfer chamber 136 and a substantially ambient (e.g., atmospheric) environment of the factory interface 102.

The transfer chamber 136 has a vacuum robot 130 disposed therein. The vacuum robot 130 has a blade 134 capable of transferring the substrates 124 between the substrate load lock chambers 122 and the processing chambers 110, 112, 132, 128, 120.

The controller 144 is coupled to the processing system 100. The controller 144 controls the operations of the system 100 using a direct control of the process chambers 110, 112, 132, 128, 120 of the system 100 or alternatively, by controlling the computers (or controllers) associated with the process chambers 110, 112, 128, 120, 132 and the system 100. In operation, the controller 144 enables data collection and feedback from the respective chambers and controller 144 to optimize performance of the system 100.

The controller 144 is used to control processes and methods, such as the operations of the methods described herein (for example the operations of the method 900 described below). The controller 144 includes a central processing unit (CPU) 138, a memory 140 containing instructions, and support circuits 142 for the CPU. The controller 144 controls various items directly, or via other computers and/or controllers. In one or more embodiments, the controller 144 is communicatively coupled to dedicated controllers, and the controller 144 functions as a central controller.

The controller 144 is of any form of a general-purpose computer processor that is used in an industrial setting for controlling various substrate processing chambers and equipment, and sub-processors thereon or therein. The memory 140, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 142 of the controller 144 are coupled to the CPU 138 for supporting the CPU 138 (a processor). The support circuits 142 can include cache, power supplies, clock circuits, input/output circuitry and subsystems, and the like. Operational parameters (such as UV light power, inert gas temperature, inert gas pressure, native oxide content, particle concentration, and/or atomic particle concentration) and operations are stored in the memory 140 as software routine(s) that are executed or invoked to turn the controller 144 into a specific purpose controller to control the operations of the various systems/chambers/units/modules described herein. The software routine(s), when executed by the CPU 138, transform the CPU 138 into a specific purpose computer. The software routines may also be stored and/or executed by a second controller (not shown) that is located remotely from the system 100.

The controller 144 is configured to conduct any of the operations described herein. The instructions stored on the memory, when executed, cause one or more of operations of method 900 (described below) to be conducted.

The various operations described herein can be conducted automatically using the controller 144, or can be conducted automatically and/or manually with certain operations conducted by a user.

The controller 144 is configured to adjust output to controls of the system 100 based off of sensor readings, a system model, and stored readings and calculations. As an example, one or more operating parameters can be measured by one or more sensors positioned along the system 100. The controller 144 includes embedded software and a compensation algorithm to calibrate measurements. The controller 144 can include one or more machine learning algorithms and/or artificial intelligence algorithms that estimate optimized parameters for deposition operation(s), cleaning operations, etching operations, and/or atomic radical treatment operation(s). The one or more machine learning algorithms and/or artificial intelligence algorithms can use, for example, a regression model (such as a linear regression model) or a clustering technique to estimate optimized parameters. The algorithm can be unsupervised or supervised.

The one or more machine learning algorithms and/or artificial intelligence algorithms can optimize the operating parameters used in relation to operations described herein.

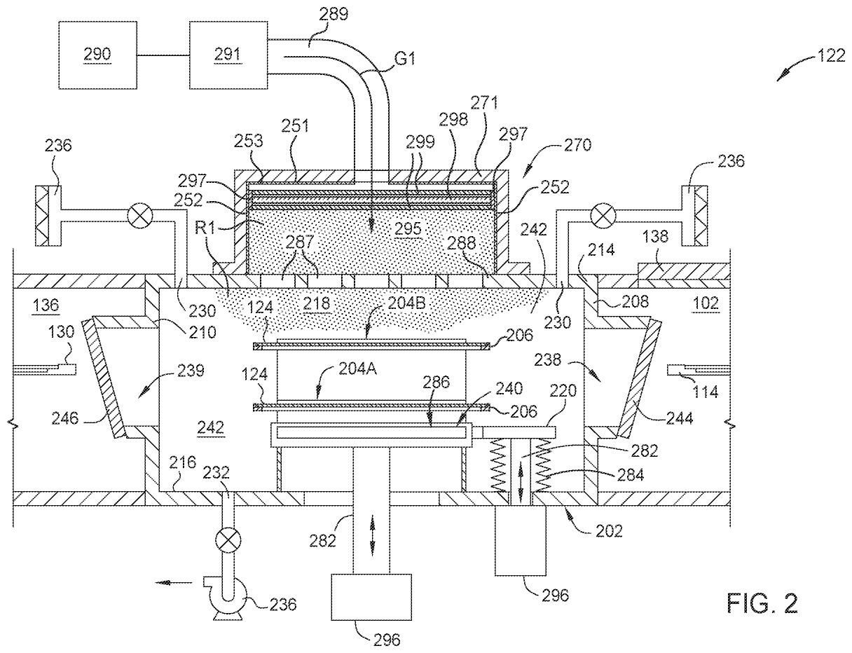

FIG. 2 is a schematic cross-sectional side view of one of the substrate load lock chambers 122 shown in FIG. 1, according to one implementation. The substrate load lock chamber 122 includes a chamber body 202, a first carrier holder 204B, a second carrier holder 204A, and a temperature-controlled pedestal 240. Each of the first carrier holder 204B and the second carrier holder 204A includes a substrate 124 supported by a carrier 206. The chamber body 202 may be fabricated from a singular body of material such as aluminum. The chamber body 202 includes a first side wall 208, a second side wall 210, lateral walls 242 (one is shown in the view of FIG. 2), a top 214, and a bottom 216 that define an internal volume 218. Windows (not shown) may be provided in the top 214 of the chamber body can be formed at least partially of quartz, or other UV transparent material(s) such as a UV transparent glass (for example fused silica glass).

The pressure of the internal volume 218 may be controlled so that the substrate load lock chamber 122 may be evacuated to substantially match the environment of the transfer chamber 136 and be vented to substantially match the environment of the factory interface 102. The chamber body 202 includes one or more vent passages 230 and a pump passage 232. The flow within the substrate load lock chamber 122 during venting and evacuation is substantially laminar due to the position of the vent passage 230 and pump passage 232 and is configured to minimize particulate contamination.

The pump passage 232 is coupled to a vacuum pump 236. The vacuum pump 236 has low vibration to minimize the disturbance of the substrate 124 positioned on the holders 204B, 204A within the substrate load lock chamber 122 while promoting pump-down efficiency and time by reducing or minimizing the fluid path between the load lock chamber 122 and pump 236 to generally less than three feet.

A first loading port 238 is disposed in the first side wall 208 of the chamber body 202 to allow the substrate 124 to be transferred between the substrate load lock chamber 122 and another device (such as the factory interface 102). A first slit valve 244 selectively seals the first loading port 238 to isolate the substrate load lock chamber 122 from the factory interface 102. A second loading port 239 is disposed in the second side wall 210 of the chamber body 202 to allow the substrate 124 to be transferred between the load lock chamber 122 and the another device (such as the transfer chamber 136). A second slit valve 246 which is substantially similar to the first slit valve 244 selectively seals the second loading port 239 to isolate the load lock chamber 122 from the vacuum environment of the transfer chamber 136.

The first carrier holder 204B is concentrically coupled to (e.g., stacked on top of) the second carrier holder 204A that is disposed above the chamber bottom 216. The carrier holders 204B, 204A are generally mounted to a support 220 that is coupled to a shaft 282 that extends through the bottom 216 of the chamber body 202. Typically, each carrier holder 204B, 204A is configured to retain one substrate positioned on a respective carrier 206. The shaft 282 is coupled to a lift mechanism 296 disposed exterior to the load lock chamber 122 that controls the elevation of the carrier holders 204B and 204A within the chamber body 202. A bellows 284 is coupled between the support 220 and the bottom 216 of the chamber body 202 and disposed around the shaft 282 to provide a flexible seal between the second carrier holder 204A and the bottom 216, facilitating preventing leakage from or into the chamber body 202 and facilitating raising and lowing of the carrier holders 204B, 204A without compromising the pressure within the load lock chamber 122.

In one or more embodiments, the first carrier holder 204B is utilized to hold an unprocessed substrate from the factory interface 102 on a first carrier 206 while the second carrier holder 204A is utilized to hold a processed substrate (e.g., an etched substrate) on a second carrier 206 returning from the transfer chamber 136. The present disclosure contemplates that each pair of carrier holder and carrier can be considered at least part of a substrate support. The present disclosure contemplates the use of other substrate supports in the load lock chamber 122.

An ultraviolet light (UV) unit 270 is coupled to the load lock chamber 122. is positioned atop the top 214 of the chamber body 202. The UV unit 270 includes a unit housing 271, one or more bulbs 299 disposed in the unit housing 271, and one or more UV light sources 298 disposed in the one or more bulbs 299. A pair of end caps 297 are coupled to the respective ends of the bulbs 299 and the UV light sources 298. The end caps 297 can be electrically connected to power source(s) to supply power to the UV light sources 298. The end caps 297 are coupled to the unit housing 271 to support the bulbs 299 and the UV light sources 298.

A gas line 289 is fluidly connected to the internal volume 218 from outside of the internal volume 218. The gas line is fluidly connected to an inert gas source 290. In one or more embodiments, the gas line 289 is at least partially formed of a ceramic and/or metallic material. In one or more embodiments, the gas line 289 is at least partially formed of aluminum, stainless steel, and/or an aluminum oxide (such as Al₂O₃). In one or more embodiments, section(s) (such as part or all) of the gas line 289 that do not have atomic radicals flowing therein are formed of metallic material(s) (such as aluminum and/or stainless steel). In one or more embodiments, section(s) (such as part or all) of the gas line 289 that do have atomic radicals flowing therein are formed of ceramic material(s) (such as Al₂O₃). In the implementation shown in FIG. 2, the gas line 289 does not have atomic radicals flowing therein. The gas line 289 can include, for example, one or more conduits (such as pipes), one or more hoses (such as flexible hoses), and/or one or more flanges. One or more flow valves can be disposed along the gas line 289.

The gas line 289 delivers an inert gas G1 (supplied from the inert gas source 290) to the UV unit 270. Optionally, a heater 291 is disposed along the gas line 289 to heat the inert gas G1 prior to the inert gas G1 flowing into the internal volume 218. In one or more embodiments, the heater 291 can heat the inert gas G1 to anneal of the substrate(s) 124 in the internal volume 218. The gas line 289 is fluidly connected to the internal volume 218 through the UV unit 270 in the implementation shown in FIG. 2.

In the UV unit 270, while the inert gas G1 flows past the one or more bulbs 299 the one or more UV light sources 298 direct UV light towards the inert gas G1. An intensity of energy of the UV light interacts with the inert gas G1 to break bonds of the inert gas G1 molecules and generate atomic radicals R1 of the inert gas G1. The atomic radicals R1 can be generated within the unit housing 271 and/or in the internal volume 218. The atomic radicals R1 then interact with one or more surfaces of the substrate(s) 124 to treat the one or more surfaces of the substrate(s) 124. The atomic radicals R1 can embed in one or more layers of the substrate(s) 124, which facilitates effective subsequent processing and reduced particle contamination of the substrate(s) 124. As an example, the embedded atomic radicals R1 can facilitate effective etching to remove a native oxide layer in one of the plurality of processing chambers 110, 112, 132, 128, 120 (e.g. an etch chamber). The UV unit 270 facilitates reliably, effectively, cheaply, and efficiently generating atomic radicals R1 of the inert gas G1. In one or more embodiments, the inert gas G1 includes hydrogen (H₂), and the atomic radicals are atomic hydrogen radicals (H*). The present disclosure contemplates the use of other gases (such as nitrogen (N₂), nitric oxide (NO), ammonia gas (NH₃) water vapor (H₂O), and/or oxygen (O₂)) to generate other atomic radicals (such as atomic nitrogen radicals and/or atomic oxygen radicals). The present disclosure contemplates that a plurality of gases can be used in place of the inert gas G1, and/or that gases other than inert gases (such as reactive gases) can be used in place of the inert gas G1.

When the substrate moves into the second loading port 239 to enter the transfer chamber 136, the substrate 124 can be transferred to one of the plurality of processing chambers 110, 112, 132, 128, 120 for processing.

In the implementation shown in FIG. 2, the atomic radicals R1 can flow through one or more flow openings 287 of a flow wall 288 and into the internal volume 218. The flow wall 288 can be omitted such that an internal unit volume 295 defined by the unit housing 271 is open to the internal volume 218.

The implementation shown in FIG. 2 shows the inert gas G1 entering the internal volume 218 through a ceiling of the internal volume. The present disclosure contemplates that the inert gas G1 can enter the internal volume 218 through a side of the internal volume 218.

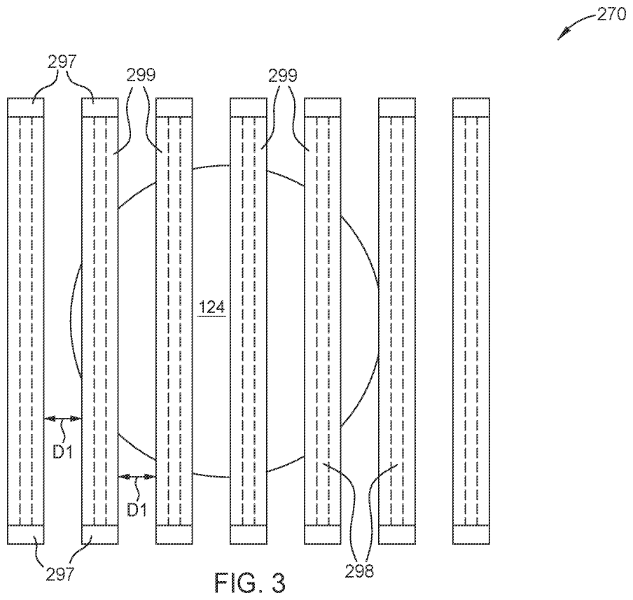

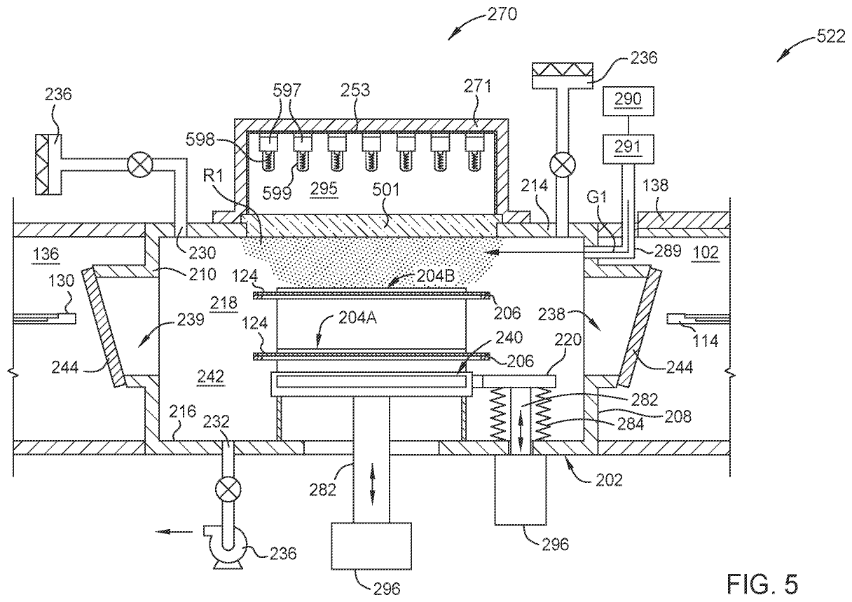

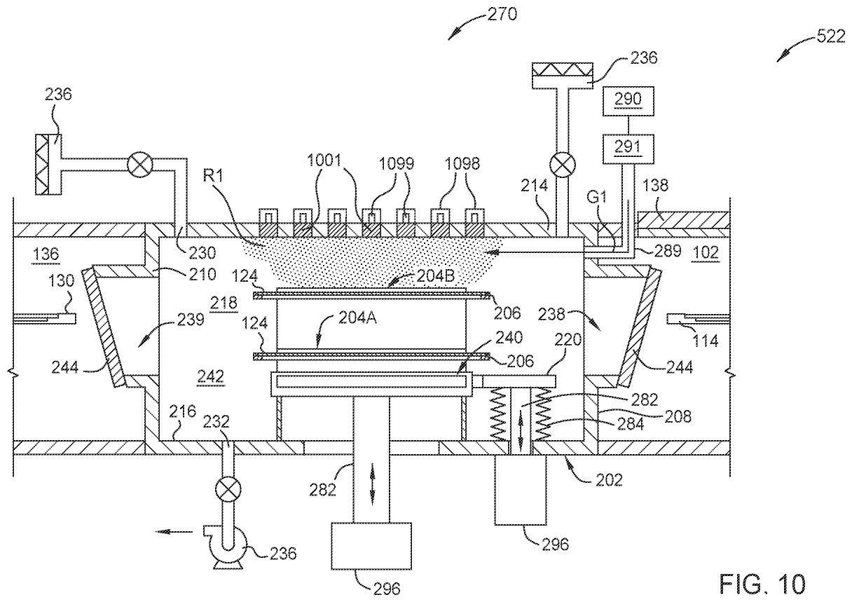

FIG. 3 is a schematic top view of the UV unit 270 shown in FIG. 2 positioned above a substrate 124, according to one implementation. The one or more UV light sources 298 (a plurality is shown) are configured to generate UV light having a wavelength that is within a range of 170 nm to 400 nm, such as within a range of 170 nm to 340 nm. In one or more embodiments the one or more bulbs 299 (a plurality is shown) are transmissive to at least 95% of the UV light. In one or more embodiments, the one or more bulbs 299 are formed of quartz. In one or more embodiments, the wavelength is a range of 170 nm to 254 nm. In one or more embodiments, the UV light has an intensity within a range of 10 mW/cm² to 10 W/cm². In one or more embodiments, the wavelength is within a range of 170 nm to 254 nm. In one or more embodiments, the wavelength is greater than 170 nm and is less than 400 nm. In one or more embodiments, the wavelength is greater than 170 nm and is less than 254 nm. In one or more embodiments, the wavelength is within a range of 172 nm to 254 nm. In one or more embodiments the wavelength is less than 254 nm. The UV unit 270 can include, for example, excimer lamps (see FIG. 3, for example), low-pressure mercury lamps (see FIG. 5, for example), UV lasers (see FIG. 10, for example), and/or or other suitable UV light generators. The UV light sources 298 can include filaments (e.g., coiled filaments), for example. The bulbs 299 can be filled with gas(es), such as noble gas(es).

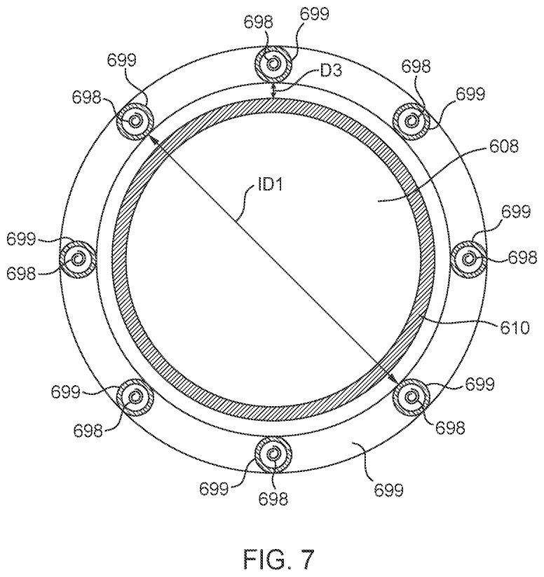

The bulbs 299 are spaced from each other by a distance D1. In one or more embodiments, the distance D1 is at least 5 mm. In one or more embodiments the distance D1 is within a range of 5 mm to 5 cm. The distance D1 can be predetermined. The distance D1 facilitates allowing the gas G1 to flow between the bulbs 299 and exposing the gas G1 to UV light to reliably generate atomic radicals R1. As shown in FIG. 3 the substrate(s) 124 are positioned beneath the bulbs 299. FIG. 7 shows seven bulbs 310 in a single row (having seven columns). The present disclosure contemplates that other configurations can be used. For example, multiple rows of bulbs can be used. As another example, the number of columns can vary from the seven shown. In one or more embodiments one or more UV reflectors 253 are used to reflect the UV light toward the substrate 124. The UV reflector(s) 253 can include a mirror, such as a mirror-like coating. The UV reflector(s) 253 can be coated or otherwise disposed or formed on inner surface(s) of the unit housing 271 (such as an upper inner surface 251 and/or side surfaces 252 of the unit housing 271 shown in FIG. 2). For example, the UV reflector(s) 253 can be smoothened inner surface(s) of the unit housing 271. The UV reflector(s) 253 can be positioned above the UV light sources 298, below the UV light sources 298, and/or about the UV light sources 298 to reflect UV light toward the substrate 124 surface.

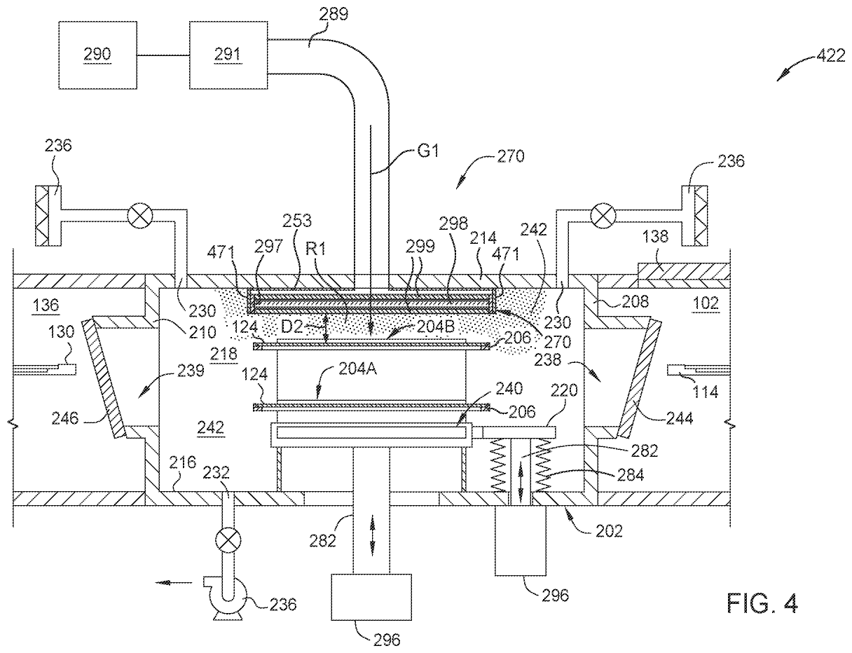

FIG. 4 is a cross-sectional view of a load lock chamber 422, according to one implementation. The load lock chamber 422 is similar to the load lock chamber 122 shown in FIG. 2, and includes one or more aspects, features, components, operations, and/or properties thereof. The load lock chamber 422 can be used in place of the one or more load lock chambers 122 shown in FIG. 1.

In the implementation shown in FIG. 4, the UV unit 270 includes one or more unit connectors 471 that extend inwardly into the internal volume 218 relative to the top 214. The UV unit 270 is positioned in the internal volume 218, and the UV unit 270 is suspended from the top 214 using the one or more unit connectors 471. The one or more unit connectors 471 couple to the end caps 297. The one or more unit connectors 471 can be part of a unit housing that at least partially (such as entirely) encloses the bulbs 299.

In the implementation shown in FIG. 4, a majority of the radicals R1 are generated in the internal volume 218 (such as between the bulbs 299, and/or between the bulbs 299 and the uppermost substrate 124). The UV light generated using the UV light sources 298 can be generated at least partially toward the uppermost substrate 124. In one or more embodiments, a distance D2 between the bulbs 299 and the uppermost substrate 124 is within a range of 1 mm to 10 cm during the generation of radicals R1 and treatment of the substrate(s) 124 using the radicals R1. The present disclosure contemplates that the distance D2 can vary depending on process parameters. The change of distance D2 can happen by moving the uppermost substrate 124 up toward or away from the UV unit 270 (e.g., by raising or lowering the carrier 206), by moving the UV unit 270 toward or away from the uppermost substrate 124, or by both moving the uppermost substrate 124 and moving the UV unit 270. As shown in FIG. 4, one or more UV reflectors 253 can be positioned (e.g., on an inner surface of the 214) to reflect UV light toward an upper surface of the uppermost substrate 124. The UV reflectors 253 can be positioned on inner surface(s) of the one or more unit connectors 471.

FIG. 5 is a cross-sectional view of a load lock chamber 522, according to one implementation. The load lock chamber 522 is similar to the load lock chamber 122 shown in FIG. 2, and includes one or more aspects, features, components, operations, and/or properties thereof. The load lock chamber 522 can be used in place of the one or more load lock chambers 122 shown in FIG. 1.

In the implementation shown in FIG. 5, one or more UV light sources 598 (a plurality is shown) disposed in one or more bulbs 599 (a plurality is shown) are coupled to the unit housing 271 using one or more unit connectors 597 (a plurality is shown). A plate 501 (e.g., a window) is disposed between the unit internal volume 295 and the internal volume 218. The plate 501 is UV transparent to allow UV light into the internal volume 218, and can be formed of a UV transparent glass (such as quartz). In one or more embodiments the plate 501 is transmissive to at least 95% of the UV light. An outer ledge 502 of the plate 501 is supported by the top 214 and/or the unit housing 271.

The gas line 289 is fluidly connected to the first sidewall 208 to supply the inert gas G1 to the internal volume 218 through the first sidewall 208. The inert gas G1 interacts with the UV light in the internal volume 218 such that radicals R1 are formed in the internal volume 218. The radicals R1 then treat the substrate(s) 124.

As described below in relation to combination of subject matter herein, the present disclosure contemplates that the UV light sources 598, the bulbs 599, and the unit connectors 597 can be replaced with the UV light sources 298, the bulbs 299, and the end caps 297 shown in FIG. 2.

The implementation shown in FIG. 5 shows the inert gas G1 entering the internal volume 218 through a side of the internal volume. The present disclosure contemplates that the inert gas G1 can enter the internal volume 218 through the ceiling of the internal volume 218.

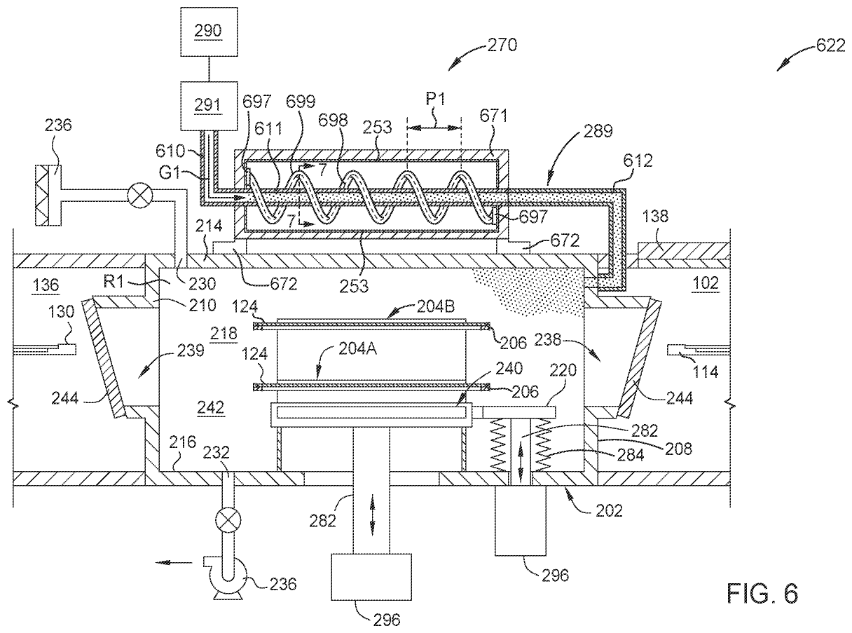

FIG. 6 is a cross-sectional side view of a load lock chamber 622, according to one implementation. The load lock chamber 622 is similar to the load lock chamber 122 shown in FIG. 2, and includes one or more aspects, features, components, operations, and/or properties thereof. The load lock chamber 622 can be used in place of the one or more load lock chambers 122 shown in FIG. 1.

The gas line 289 includes a UV transparent section 610 disposed within the UV unit 270 (e.g., within a unit housing 671), and a second section 611. In the implementation shown, the second section 611 is a downstream section. In one or more embodiments, the UV transparent section 610 is formed of a UV transparent glass (such as quartz or fused silica glass). The second section 611 includes a material that is metallic or ceramic (such as metallic or ceramic material(s) described above, e.g., aluminum, stainless steel, and/or an aluminum oxide (such as Al₂O₃)). The second section 611 can be formed of the material that is metallic or ceramic, or can have an inner coating that is metallic or ceramic.

In the implementation shown in FIG. 6, the internal unit volume 295 is part of a line opening of the UV unit 270. The UV unit 270 is disposed at least partially about the gas line 289 such that the gas line 289 extends through the UV unit 270 (e.g., through the unit housing 671 and through one or more arcuate bulbs 699 of the UV unit 270).

The one or more arcuate bulbs 699 are disposed at least partially about the gas line 289, and one or more UV light sources 698 are disposed in the one or more arcuate bulbs 699. In the implementation shown in FIG. 6, the one or more arcuate bulbs 699 are one or more tubes that spiral around the gas line 289 (e.g., the first section 611 of the gas line 289) in a helical pattern.

Radicals R1 are generated in a flow volume 608 (e.g., an inner volume) of the first section 611 of the gas line 289, and the gas line 289 supplies the radicals R1 to the internal volume 218.

FIG. 7 is a schematic cross-sectional view of the UV 270 unit shown in FIG. 6, along Section 7-7 shown in FIG. 6, according to one implementation. The sectional view shown in FIG. 7 is perpendicular to the sectional view shown in FIG. 6.

As shown in FIGS. 6 and 7, the one or more arcuate bulbs 699 include a plurality of spiraled sections that encircle an outer perimeter (e.g., an outer circumference) of the gas line 289. The one or more arcuate bulbs 699 can be a single arcuate bulb (as shown in FIG. 6), or a plurality of arcuate bulbs. The one or more UV light sources 698 can be a single UV light source (as shown in FIG. 6), or a plurality of UV light sources.

A radial distance D3 between the one or more arcuate bulbs 699 and the first section 610 is within a range of 1 mm to 15 mm. In one or more embodiments, a plurality of arcuate bulbs 699 (eight is shown in FIG. 7) and a plurality of UV light sources (eight is shown in FIG. 7) each spiral around the gas line 289 in the helical pattern (as is shown for the single arcuate bulb 699 in FIG. 6). In FIG. 7, eight arcuate bulbs 699 are shown but fewer or more can be used. As shown in FIG. 6 each of the arcuate bulbs 699 spiral around the UV transparent first section 610 of the gas line 289. In the implementation shown in FIG. 7, each arcuate bulb 699 is a helix tube. An inner diameter ID1 of each arcuate bulb 699 is within a range of 5 mm to 30 mm. A pitch P1 (shown in FIG. 6) between the peaks of each arcuate bulb 699 is within a range of 5 mm to 100 mm.

In the implementation shown in FIG. 6, the unit housing 671 encloses (e.g., surrounds) the first section 611 and the one or more arcuate bulbs 699. The unit housing 671 is removably coupled to the top 214 and/or the gas line 289. The unit housing 671 can be removably coupled to other components of a processing system. In the implementation shown in FIG. 6, the unit housing 671 is removably coupled to the top 214 using one or more legs 672 (e.g., brackets such as L-shaped brackets). Fasteners can fasten the one or more legs 672 to the top 214 and/or the one or more legs 672 can rest on the top 214. Other configurations are contemplated.

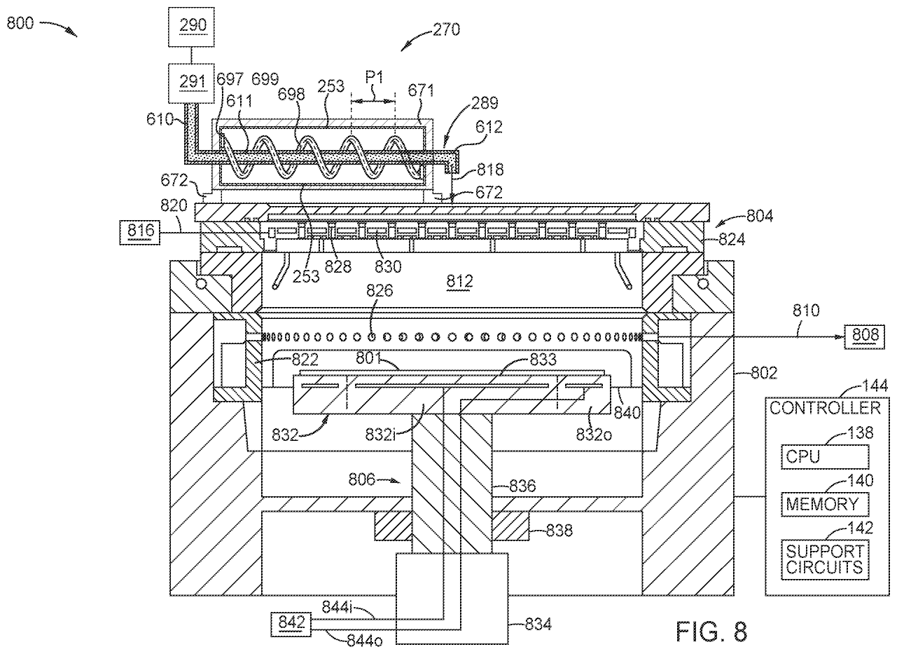

FIG. 8 is a schematic cross-sectional side view of a processing chamber 800, according to one implementation. In one or more embodiments, the processing chamber 800 is configured to perform a pre-cleaning process.

In one or more embodiments, the processing chamber 800 uses hydrogen fluoride (HF) and water (H₂O) to etch and remove native oxide (such as interfacial oxygen) of substrates. The processing chamber 800 can etch, for example, silicon oxide (such as SiO₂) selectively relative to silicon nitride (SiN).

The processing chamber 800 may be a pre-clean chamber available from Applied Materials, Santa Clara, California. The processing chamber 800 includes a chamber body 802, a lid assembly 804, and a substrate support assembly 806. The lid assembly 804 is disposed at an upper end of the chamber body 802, and the substrate support assembly 806 is at least partially disposed within the chamber body 802. A vacuum system is used to remove gases from the processing chamber 800. The vacuum system includes a vacuum pump 808 coupled to a vacuum port 810 disposed in the chamber body 802. A pumping ring 822 is disposed within the chamber body 802. The pumping ring 822 has a plurality of exhaust ports 826 providing fluid communication between the inside of the processing chamber 800 and the vacuum port 810 for exhausting gas therethrough.

The lid assembly 804 includes a plurality of stacked components configured to provide gases to a processing region 812 within the chamber 800. The lid assembly 804 is fluidly connected to the UV unit 270 (which is shown according to the implementation shown in FIGS. 6 and 7) and/or a second gas source 816. Gas(es) from the inert gas source 290 are introduced to the lid assembly 804 through a top port 818. Gas(es) from the second gas source 816 are introduced to the lid assembly 804 through a side port 820. The inert gas source 290 is fluidly connected to the top port 818 through the gas line 289. The gas line 289 has helix tubes 610 that radiate UV light. The UV unit 270 is used to generate radicals R1, and the radicals R1 are supplied to the processing region 812 through the top port 818 and the lid assembly 804.

In one or more embodiments, a third gas source may provide at least a first part of a process gas (e.g., a reactive gas). In one or more embodiments, the second gas source 816 may provide a second part of the process gas (e.g., a vapor). In one or more embodiments, one or more purge gases and/or carrier gases may also be delivered to the processing region 812 from the first gas source 814, second gas source 816, or from another gas source.

The lid assembly 804 includes a showerhead 824 disposed above the processing region 812 through which gases are introduced to the processing region 812. The showerhead 824 may include one or more additional plates (e.g., blocker plate, faceplate) disposed above the plate shown in FIG. 8. Each plate of the showerhead 824 may include multiple apertures formed therethrough which connect gas regions above and below each respective plate. In one or more embodiments, the showerhead 824 may be heated. In one or more embodiments, gases may be mixed in or above the showerhead 824 during heating. In one or more embodiments, the showerhead 824 may be heated to about 190° C. while a substrate to be processed is at about 10° C.

In the implementation shown in FIG. 8, the showerhead 824 is a dual channel showerhead which has a first set of channels 828 and a second set of channels 830. The first set of channels 828 provides fluid communication above and below a plane of the showerhead 824 for gases from the top port 818 to enter the processing region 812. The second set of channels 830 provides fluid communication with the side port 820 for gases from the second gas source 816 to enter the processing region 812. The dual channel showerhead may be advantageous to improve mixing of different gases coming from the inert gas source 290, the second gas source 816, and or the third gas source.

The substrate support assembly 806 (also referred to as a “pedestal”) includes a support body 832 (also referred to as a “puck”) to support a substrate 801 thereon during processing and a stem 836 coupled to the support body 832.

The support body 832 includes a top surface having a flat, or a substantially flat, substrate-supporting surface 833 (also referred to as a “substrate-supporting area” or “substrate contact surface” of the support body 832). In one or more embodiments, the substrate-supporting surface 833 may extend a radial distance R1 from a center C1 of the support body 832.

As shown in FIG. 8, the support body 832 includes two independent temperature control zones (referred to as “dual zone”) to control substrate temperature for center-to-edge processing uniformity and tuning. In the implementation illustrated in FIG. 8, the support body 832 has an inner zone 832i and an outer zone 8320 surrounding the inner zone 832i. In one or more embodiments, the support body 832 may have more than two independent temperature control zones (referred to as “multi zone”).

The support body 832 is coupled to an actuator 834 by the stem 836 which extends through a centrally-located opening formed in a bottom of the chamber body 802. The actuator 834 is flexibly sealed to the chamber body 802 by bellows 838 that prevent vacuum leakage around the stem 836. The actuator 834 allows the support body 832 to be moved vertically within the chamber body 802 between a processing position and a loading position. The loading position is slightly below a substrate opening 840 formed in a sidewall of the chamber body 802.

The processing chamber 800 also includes an ultra-low temperature kit 842 for lowering a temperature of the substrate to be processed, which can improve selectivity for oxide removal (e.g., native oxide removal) compared to other materials, such as low-k dielectric materials and silicon nitride (e.g., SiN), among others. In one or more embodiments, the temperature of the substrate to be processed and/or a temperate of the support body 832 may be lowered to about −30° C. to about 10° C. The ultra-low temperature kit 842 provides a continuous flow of ultra-low temperature coolant to the support body 832 which cools the support body 832 to a desired temperature. In one or more embodiments, the ultra-low temperature coolant may include perfluorinated, inert polyether fluids. In the implementation illustrated in FIG. 8, the ultra-low temperature coolant is provided to the inner zone 832i and outer zone 8320 of the support body 832 through inner coolant channel 844i and outer coolant channel 8440, respectively. The coolant channels are drawn schematically in FIG. 8 and may have a different arrangement from what is shown. For example, each coolant channel may be in the form of a loop. The controller 144 is connected to the processing chamber 800 (as also shown in FIG. 1).

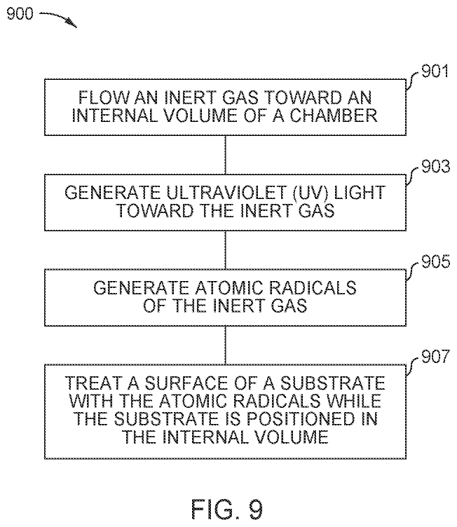

FIG. 9 is a schematic block diagram view of a method of processing substrates, according to one implementation.

Operation 901 includes flowing an inert gas toward an internal volume of a chamber (e.g., through the gas line 289).

In one or more embodiments, the inert gas is hydrogen. In one or more embodiments, the inert gas is oxygen or nitrogen. In one or more embodiments, the inert gas includes a combination of hydrogen, nitrogen, oxygen, and/or other gas(s).

Operation 903 includes generating ultraviolet (UV) light toward the inert gas. In one or more embodiments, the UV light has a wavelength as described above.

Operation 905 includes generating atomic radicals of the inert gas. The UV light interacts with the inert gas to break bonds between atoms and generate the atomic radicals. In one or more embodiments, the UV light source has a power within a range of 100 Watts (W) to 600 W. In one or more embodiments, the power is within a range of 200 W to 500 W. In one or more embodiments, the power of the UV light is 200 W. In one or more embodiments, the power of the UV light is 500 W. The intensity of light exposed to the inert gas can be controlled in two ways. The first is to control voltage power which affects the power of the light. The second is the distance (which can be affected by the distance D2 and/or the distance D3 described above) of light transmission and/or light reflection. In one or more embodiments, the inert gas flows at a temperature that is an ambient temperature (e.g., room temperature) or higher. In one or more embodiments, the inert gas flows at a temperature within a range of 95 degrees Celsius to 105 degrees Celsius. In one or more embodiments, the temperature is about 100 degrees Celsius. Other values for the temperature are contemplated. The substrate can be at a substrate temperature that is 300 degrees Celsius or lower, for example. Other values for the substrate temperature are contemplated.

Operation 907 includes treating a surface of a substrate with the atomic radicals while the substrate is positioned in the internal volume of the chamber. The hydrogen radicals come into contact with the surface of the substrate and embed in the substrate. The hydrogen radicals treat a surface of a substrate.

FIG. 10 is a cross-sectional view of a load lock chamber 1022, according to one implementation. The load lock chamber 1022 is similar to the load lock chamber 522 shown in FIG. 5, and includes one or more aspects, features, components, operations, and/or properties thereof. The load lock chamber 1022 can be used in place of the one or more load lock chambers 122 shown in FIG. 1.

In the implementation shown in FIG. 10, one or more UV light sources include one or more UV lasers 1099 (a plurality is shown) are disposed in one or more UV laser modules 1098 (a plurality is shown). The UV laser modules 1098 are coupled to the top 214. An optical element 1001 (such as a lens or a beam expander) is disposed between each UV laser module 1098 and the internal volume 219. The optical element(s) 1001 can be disposed in openings formed in the top 214. The UV laser modules 1098 can respectively include module housings that are removably coupled to the optical element(s) 1001 and/or the top 214. The optical element(s) 1001 are UV transparent to allow UV light into the internal volume 218, and can be formed of glass (such as quartz or fused silica glass). In one or more embodiments the optical element(s) 1001 are transmissive to at least 95% of the UV light.

The UV lasers 199, the UV laser modules 1098, and the optical element(s) 1001 can be disposed internally or externally to the load lock chamber 1022. For example, the UV lasers 199, the UV laser modules 1098, and the optical element(s) 1001 can be disposed outside of the internal volume 218 (as shown in FIG. 10) or within the internal volume 218. The present disclosure contemplates that the optical elements 1001 can be positioned in and/or mounted to a window (such as the plate 501 shown in FIG. 5).

The gas line 289 is fluidly connected to the first sidewall 208 to supply the inert gas G1 to the internal volume 218 through the first sidewall 208. The inert gas G1 interacts with the UV light provided by the UV lasers 1099 in the internal volume 218 such that radicals R1 are formed in the internal volume 218. The radicals R1 then treat the substrate(s) 124.

As described below in relation to combination of subject matter herein, the present disclosure contemplates that the UV laser modules 1098 and the UV lasers 1099 can be used in addition to, replaced with, or used in place of the UV light sources 298, the bulbs 299, the end caps 297, the unit connectors 597, the UV light sources 598, and/or the one or more bulbs 599.

The implementation shown in FIG. 10 shows the inert gas G1 entering the internal volume 218 through a side of the internal volume. The present disclosure contemplates that the inert gas G1 can enter the internal volume 218 through the ceiling of the internal volume 218. Benefits of the present disclosure include minimizing space needed for processing as treatment of substrates for particle contamination can be done in existing chambers in a processing system; reduced costs; modularity and simplicity in retrofitting a variety of chambers that conduct different operations (e.g., different processing operations); reduced contamination; and reduced particle generation. For example, the present disclosure can save costs of acquiring additional chambers for treatment. As another example, a variety of chambers used in production can be retrofitted with the implementations in the present disclosure without many changes to the chamber(s) due to the modularity of the implementations. As an additional example, present disclosure is simple and can cause less exposure to contaminants and corrosion plasma is not necessarily needed to create radicals. The present disclosure is also versatile due to functionality in high and low pressure chambers. As a further example, the UV units described herein (for example the UV units positioned outside of chambers, such as the UV unit 270 implementation shown in FIG. 6) are modular and can be used to retrofit a variety of chambers at operating sites such that modifications to the chambers are reduced.

Using UV light in the wavelength range of 170 nm-254 nm facilitates exemplary benefits. For example, the range facilitates reliable, effective, inexpensive, and efficient breaking of bonds of molecules for radical generation while also reducing effects (such as particle generation, unintentional etching and/or melting, contamination, and hindered device performance) on substrates and other components. The range also reduces interference with other processing operations (such as cleaning, etching, or deposition).

The present disclosure described UV units used in relation to load lock chambers and processing (e.g., pre-clean) chambers. The present disclosure contemplates that the UV units described herein can be used in relation to a variety of other chambers (such as epitaxial deposition chambers and/or plasma chambers, for example).

It is contemplated that one or more aspects disclosed herein may be combined. As an example, one or more aspects, features, components, operations and/or properties of the processing system 100, the load lock chamber 122, the inert gas source 290, the heater 291, the gas line 289, the various UV unit 270 implementations, the load lock chamber, 422, the load lock chamber 522, the plate 501, the load lock chamber 622, the processing chamber 800, and/or the method 900 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A chamber applicable for use in semiconductor manufacturing, comprising:
one or more sidewalls;
an internal volume defined at least partially by the one or more sidewalls;
one or more substrate supports disposed in the internal volume;
one or more transfer openings formed in the one or more sidewalls;
a gas line fluidly connecting to the internal volume from outside of the internal volume;
an ultraviolet (UV) unit, the UV unit comprising:
one or more UV light sources configured to generate UV light having a wavelength that is within a range of 170 nm to 254 nm.

2. The chamber of claim 1, wherein the UV unit is positioned outside of the internal volume and facing the gas line, and the one or more UV light sources are configured to generate the UV light toward a flow volume of the gas line.

3. The chamber of claim 2, wherein the gas line extends through the UV unit such that a gas in the flow volume is exposed to the UV light prior to flowing into the internal volume.

4. The chamber of claim 3, wherein the gas line comprises a UV transparent section disposed within the UV unit, and a downstream section between the UV transparent section and the internal volume, the downstream section including a material that is metallic or ceramic.

5. The chamber of claim 2, further comprising a UV transparent plate between the UV unit and the internal volume, wherein the UV transparent plate at least partially defines a ceiling of the internal volume.

6. The chamber of claim 1, further comprising a heater disposed along the gas line to heat a gas in the gas line prior to flowing into the internal volume.

7. The chamber of claim 1, wherein the one or more UV light sources are disposed in a plurality of bulbs that are cylindrical and oriented parallel to each other, wherein the plurality of bulbs are spaced from each other by a distance to allow a gas to flow through a plurality of spaces between the plurality of bulbs.

8. The chamber of claim 1, wherein the one or more UV light sources are disposed in one or more bulbs, and the one or more bulbs of the UV unit are arcuate and disposed at least partially around the gas line.

9. The chamber of claim 8, wherein the one or more bulbs are spiraled around the gas line in a helical pattern.

10. The chamber of claim 1, wherein the one or more UV light sources comprise one or more UV lasers.

11. An apparatus applicable for use in semiconductor manufacturing, comprising:
a gas line at least partially formed of a UV transparent material, the gas line comprising a flow volume;
an ultraviolet (UV) unit comprising a line opening and configured to be disposed at least partially about the gas line such that the gas line extends through the UV unit, the UV unit comprising:
one or more arcuate bulbs configured to be disposed at least partially around the gas line, and
one or more UV light sources disposed in the one or more arcuate bulbs, the one or more UV light sources configured to generate UV light, the UV light having a wavelength that is within a range of 170 nm to 400 nm.

12. The apparatus of claim 11, wherein the gas line comprises a UV transparent section disposed within the UV unit, and a second section, the second section including a material that is metallic or ceramic.

13. The apparatus of claim 11, wherein the one or more arcuate bulbs are spiraled around the gas line in a helical pattern.

14. The apparatus in claim 11, wherein the one or more arcuate bulbs comprise a plurality of spiraled sections that encircle an outer perimeter of the gas line.

15. A method of processing substrates, comprising:
flowing an inert gas toward an internal volume of a chamber;
generating ultraviolet (UV) light toward the inert gas, the UV light having a wavelength that is within a range of 170 nm to 400 nm;
generating atomic radicals of the inert gas; and
treating a surface of a substrate with the atomic radicals while the substrate is positioned in the internal volume of the chamber.

16. The method of claim 15, wherein the UV light is directed radially toward the inert gas.

17. The method of claim 15, wherein the inert gas flows through a ceiling or a side of the internal volume, and the inert gas is exposed to the UV light in the internal volume.

18. The method of claim 15, wherein the inert gas is exposed to the UV light in a gas line outside of the internal volume, and the atomic radicals flow through a ceiling or a side of the internal volume.

19. The method of claim 15, wherein the inert gas is hydrogen (H₂), and the atomic radicals are atomic hydrogen radicals (H*).

20. The method of claim 15, wherein:
the wavelength is greater than 170 nm and is less than 254 nm
the UV light has a power within a range of 100 Watts to 600 Watts; and
the inert gas flows at a temperature that is a room temperature or higher.
